(19) United States
(12) Patent Application Publication
(10) Pub. No.: US 2018/0138230 A1
(43) Pub. Date: May 17, 2018

(54) COMPOSITE PHOTODIODE AND PHOTOSENSOR USING THE SAME

(71) Applicant: Rohm Co., Ltd., Kyoto (JP)

(72) Inventor: Yoshitsugu UEDAIRA, Kyoto (JP)

(21) Appl. No.: 15/813,920

(22) Filed: Nov. 15, 2017

(30) Foreign Application Priority Data
Nov. 17, 2016 (JP) 2016223805

(51) Int. Cl. H01L 27/146; H01L 31/02

(52) U.S. Cl. CPC H01L 27/14645; H01L 31/02005; H01L 31/03529; H01L 27/14649; H01L 27/14636; H01L 31/02019

(57) ABSTRACT

A composite photodiode includes a first photodiode, a second photodiode, and a third photodiode, each of which has an anode and a cathode. The cathode of the first photodiode is connected to a first circuit connection node, the anode of the first photodiode is commonly connected to the anode of the second photodiode and is connected to a second circuit connection node, the cathode of the second photodiode is commonly connected to the cathode of the third photodiode and is connected to a third circuit connection node, and the anode of the third photodiode is connected to a fourth circuit connection node.

### CROSS-REFERENCE TO RELATED APPLICATIONS

This nonprovisional application claims priority under 35 U.S.C. § 119(a) on Patent Application No. 2016-223805 filed in Japan on Nov. 17, 2016, the entire contents of which are hereby incorporated by reference.

### BACKGROUND OF THE INVENTION

### Field of the Invention

The invention disclosed in this specification relates to a composite photodiode and a photosensor using the same.

### Description of Related Art

A photosensor that detects components of light includes a plurality of light receiving portions (RGB). Each of the light receiving portions is required to uniformly receive light, so as to uniformly respond to not only light from the front but also light from an oblique direction. However, light may enter not only from the front surface of a chip but also from a side surface of the chip. The light entering from a side surface of the chip affects uniformity of light.

In general, a photosensor is enclosed in a transparent package, and hence light enters not only from the front surface of the chip but also from a side surface of the chip. In addition, light reflected from a circuit board on which the photosensor is mounted also enters from a side surface of the chip, and hence extra light enters beyond expectation.

JP-A-2006-148014 (hereinafter referred to as Patent Document 1) provides an inexpensive visible light illuminance sensor that is not affected by infrared light entering from a side surface. With reference to FIG. 6 of Patent Document 1, as countermeasures against entering infrared light, a third photodiode having sensitivity in an infrared light range is formed so as to enclose side and bottom surfaces of each of a first photodiode having sensitivity mainly in a visible light range and a second photodiode having sensitivity mainly in the infrared light range. A positive terminal and a negative terminal of the third photodiode are short-circuited, and hence infrared light entering from a side surface of the semiconductor substrate is absorbed by the third photodiode. Further, because the current thereof is consumed, a current signal generated in the third photodiode hardly flows into the first and second photodiode regions, and thus influence of the infrared light entering from a side surface can be reduced to such a level that no problem occurs in practical use.

JP-A-2014-207392 (hereinafter referred to as Patent Document 2) suppresses noise current due to carriers generated by incident light from a tip end surface. For this purpose, a p-well is disposed between a photodiode region and a chip end surface, and a reverse bias is applied to the p-well so that a wide depletion layer is formed and is contacted with a high-concentration n-type substrate. Because the photodiode region is enclosed by the depletion layer generated at a pn junction of the p-well and the high-concentration n-type substrate in the lower part, the carriers generated by light entering from a chip end surface can be prevented from entering the photodiode region.

JP-A-2016-115746 (hereinafter referred to as Patent Document 3) provides a photodetection device and an electronic device. With respect to FIGS. 3 and 4 of Patent Document 3, signal detecting light receiving portions R1, G1, and B1 and infrared light receiving portions R2, G2, and B2, each of which is constituted of a photodiode 11, are formed on a semiconductor substrate 8. In addition, FIG. 5 of Patent Document 3 shows an enlarged view of the photodiode 11. With reference to FIG. 5, the photodiode 11 includes a photodiode Di1, a photodiode Di2, and a photodiode Di3, which include pn junction portions having different depths from a surface 8A of the semiconductor substrate 8. In addition, FIG. 2 of Patent Document 3 shows a layout of light-receiving regions of the photodetection device.

However, in the visible light illuminance sensor described in Patent Document 1, it is necessary to make a pnpnp structure for each element of the photosensor having a plurality of light receiving portions (RGB), and hence the layout area is increased. In addition, Patent Document 1 discloses no information about adjusting each depletion layer width of the composite photodiode.

In addition, Patent Document 2 does not suggest anything about a composite photodiode and adjusting each depletion layer width of the composite photodiode.

In addition, Patent Document 3 discloses a structure of a composite photodiode, but does not suggest anything about an equivalent circuit of the composite photodiode and adjusting each depletion layer width of the composite photodiode.

### SUMMARY OF THE INVENTION

The invention disclosed in this specification is made in view of the problems described above, and it is an object of the invention to provide a composite photodiode, which is capable of suppress arrival of undesired incident light from a chip side surface or end surface to a plurality of light receiving portions (e.g. RGB), and is capable of easily setting adjustment of depletion layer width of each photodiode without affecting other photodiodes so that spectral sensitivity characteristics of the photodiodes can be individually adjusted. In addition, it is also an object to provide a photosensor using this composite photodiode.

A composite photodiode disclosed in this specification includes a first photodiode, a second photodiode, and a third photodiode, each of which has an anode and a cathode. The cathode of the first photodiode is connected to a first circuit connection node, the anode of the first photodiode is commonly connected to the anode of the second photodiode and is connected to a second circuit connection node, the cathode of the second photodiode is commonly connected to the cathode of the third photodiode and is connected to a third circuit connection node, and the anode of the third photodiode is connected to a fourth circuit connection node.

Note that other features, elements, steps, advantages, and characteristics of the present invention will become more apparent from the description of the best mode embodiment given below and the related attached drawings.

### BRIEF DESCRIPTION OF THE DRAWINGS

FIG. 1 is an equivalent circuit diagram of a composite photodiode according to the present invention.

FIGS. 2A to 2D are diagrams showing examples of connections of photodiodes when the composite photodiode of FIG. 1 is used for a photosensor of the present invention.

FIG. 3 is a cross-sectional view showing an example in which the composite photodiode of FIGS. 2A to 2D is structured on a semiconductor substrate.

FIG. 4 is a diagram showing irradiation directions and irradiation angles when measuring output characteristics of the composite photodiode of FIGS. 2A to 2D.

FIG. 5 is a graph of light output characteristics measured according to the light irradiation directions and angles shown in FIG. 4.

FIG. 6 is a layout diagram of light-receiving regions of the photosensor using the composite photodiode according to the present invention.

### DETAILED DESCRIPTION OF THE PREFERRED EMBODIMENTS

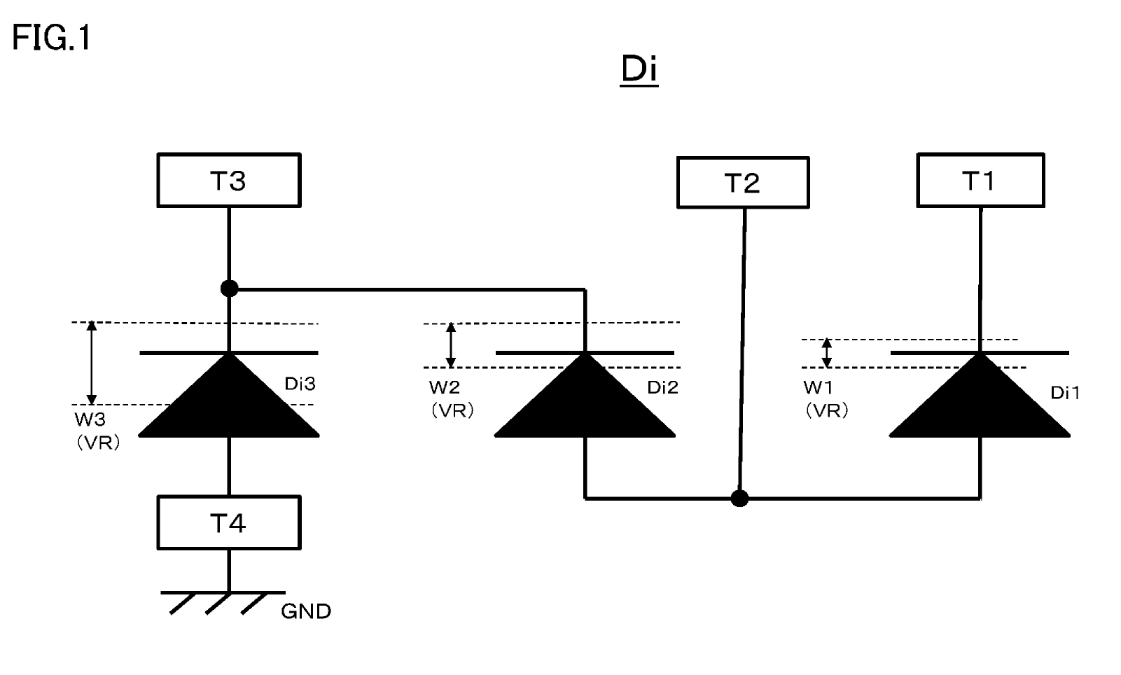

Hereinafter, an embodiment of the present invention is described with reference to the drawings. FIG. 1 is an equivalent circuit diagram of a composite photodiode according to the present invention. A composite photodiode Di is constituted of four circuit connection nodes and three photodiodes.

The cathode of a first photodiode Di1 is connected to a first circuit connection node T1. The anode of the first photodiode Di1 is connected to a second circuit connection node T2.

The anode of a second photodiode Di2 is connected to the second circuit connection node T2. Therefore the anode of the second photodiode Di2 is commonly connected to the anode of the first photodiode Di1. The cathode of the second photodiode Di2 is connected to a third circuit connection node T3.

The cathode of a third photodiode Di3 is connected to the third circuit connection node T3. Therefore the cathode of the third photodiode Di3 is commonly connected to the cathode of the second photodiode Di2. The anode of the third photodiode Di3 is connected to a fourth circuit connection node T4. The fourth circuit connection node T4 is connected to a reference potential (e.g. a ground potential GND).

In general, a photodiode is usually used by applying a reverse bias voltage between anode and cathode or by applying the same potential to the anode and the cathode. For this reason, as to the first photodiode Di1 for example, a potential applied to the first circuit connection node T1 is set to be higher than or equal to a potential applied to the second circuit connection node T2. When the first photodiode Di1 is used, a reverse bias voltage or the same potential is applied between the first circuit connection node T1 and the second circuit connection node T2. In this case, the second circuit connection node T2 and the third circuit connection node T3 are commonly connected and applied with a potential of 0.5 to 1.5 V, for example. Photocurrent flowing in the first photodiode Di1 is extracted from an output terminal of an analog-to-digital converter (ADC) whose input terminal is connected to the first circuit connection node T1, in which an analog signal is converted into a digital signal. Here, depletion layer width between cathode and anode of the first photodiode Di1 when a reverse bias voltage VR is applied to the first photodiode Di1 is denoted by symbol W1. Note that a predetermined potential is applied between the third circuit connection node T3 and the fourth circuit connection node T4 when the first photodiode Di1 is used, and hence the third photodiode Di3 functions as a photodiode. However, the ADC is not connected to the third circuit connection node T3 or the fourth circuit connection node T4, and hence only the photocurrent flowing in the first photodiode Di1 is processed by the ADC.

The second photodiode Di2 is set so that a voltage applied to the third circuit connection node T3 is higher than or equal to a voltage applied to the second circuit connection node T2. When the second photodiode Di2 is used, there are two possible methods. One of them is to connect the first circuit connection node T1 to the second circuit connection node T2. In this way, cathode and anode of the first photodiode Di1 are short-circuited, and existence of the first photodiode Di1 can be excluded. The other method is to enable the first photodiode Di1 to function in parallel. In either method, photocurrent flowing in the second photodiode Di2 is detected and processed by the ADC that is connected to the second circuit connection node T2. Here, the depletion layer width between cathode and anode of the second photodiode Di2 when the reverse bias voltage VR is applied to the second photodiode Di2 is denoted by symbol W2. Note that a predetermined potential is applied between the third circuit connection node T3 and the fourth circuit connection node T4 when the second photodiode Di2 is used, and hence the third photodiode Di3 functions as a photodiode. However, the ADC is not connected to the third circuit connection node T3 or the fourth circuit connection node T4, and hence only the photocurrent flowing in the second photodiode Di2 or the sum of the photocurrent flowing in the second photodiode Di2 and the photocurrent flowing in the first photodiode Di1 is processed by the ADC.

The third photodiode Di3 is set so that a voltage applied to the third circuit connection node T3 is higher than or equal to a voltage applied to the fourth circuit connection node T4. The fourth circuit connection node T4 is connected to the ground potential GND. When the third photodiode Di3 is used, the first circuit connection node T1 and the second circuit connection node T2 are commonly connected to the third circuit connection node T3. In this way, existence of the first photodiode Di1 and the second photodiode Di2 can be excluded. Here, the depletion layer width between cathode and anode of the third photodiode Di3 when the reverse bias voltage VR is applied to the third photodiode Di3 is denoted by symbol W3. Note that when the third photodiode Di3 is used, the first circuit connection node T1 and the second circuit connection node T2 are both connected to the third circuit connection node T3 so that operations of the first photodiode Di1 and the second photodiode Di2 are excluded, and hence only the photocurrent flowing in the third photodiode Di3 is processed.

It is known that photosensitivity of each photodiode described above is proportional to the depletion layer width. By increasing the depletion layer width, the photosensitive region is enlarged, and an effect of increasing the photocurrent can be obtained.

In FIG. 1, the reverse bias voltages applied to the photodiodes have the same voltage value VR, and the depletion layer widths W1, W2, and W3 are set so that a relationship W1<W2<W3 is satisfied. Therefore, the three photodiodes are set to have different spectral sensitivity characteristics. It is known that the depletion layer width is determined by impurity concentrations of the anode and the cathode, and the reverse bias voltage. In the present invention, by using different depletion layer widths, it is possible to provide a plurality of (e.g. three) photodiodes having different spectral sensitivity characteristics.

What is capable of having a large adjustment range of the depletion layer width is the first photodiode Di1, and there is a rational reason for this. It is because the cathode of only the first photodiode Di1 is connected to the first circuit connection node T1, and hence a predetermined reverse bias voltage can be applied between the first circuit connection node T1 and the second circuit connection node T2 so that the depletion layer width can be adjusted to a desired value, without affecting other photodiodes. Therefore the depletion layer width W1 of the first photodiode Di1 is smaller but has larger adjustable range than each of the depletion layer widths W2 and W3 of the other two photodiodes Di2 and Di3, in comparison by the same reverse bias voltage VR.

The adjustment of the depletion layer width W2 of the second photodiode Di2 is performed by changing the reverse bias voltage applied between the third circuit connection node T3 and the second circuit connection node T2. The depletion layer width W2 at the predetermined reverse bias voltage VR is larger than the depletion layer width W1 of the first photodiode Di1 but the adjustment range of the depletion layer width is smaller than that of the depletion layer width W1 of the first photodiode Di1. It is because the cathode is connected to the third circuit connection node T3, and hence the adjustment affects the third photodiode Di3.

The adjustment of the depletion layer width W3 of the third photodiode Di3 is performed by changing the reverse bias voltage applied between the third circuit connection node T3 and the fourth circuit connection node T4. The depletion layer width W3 at the predetermined reverse bias voltage VR is larger than the depletion layer width W1 of the first photodiode Di1 and than the depletion layer width W2 of the second photodiode Di2, so that a relationship of W3>W2>W1 is satisfied. The adjustment range of the depletion layer width W3 of the third photodiode Di3 is smaller than those of other two photodiodes Di1 and Di2.

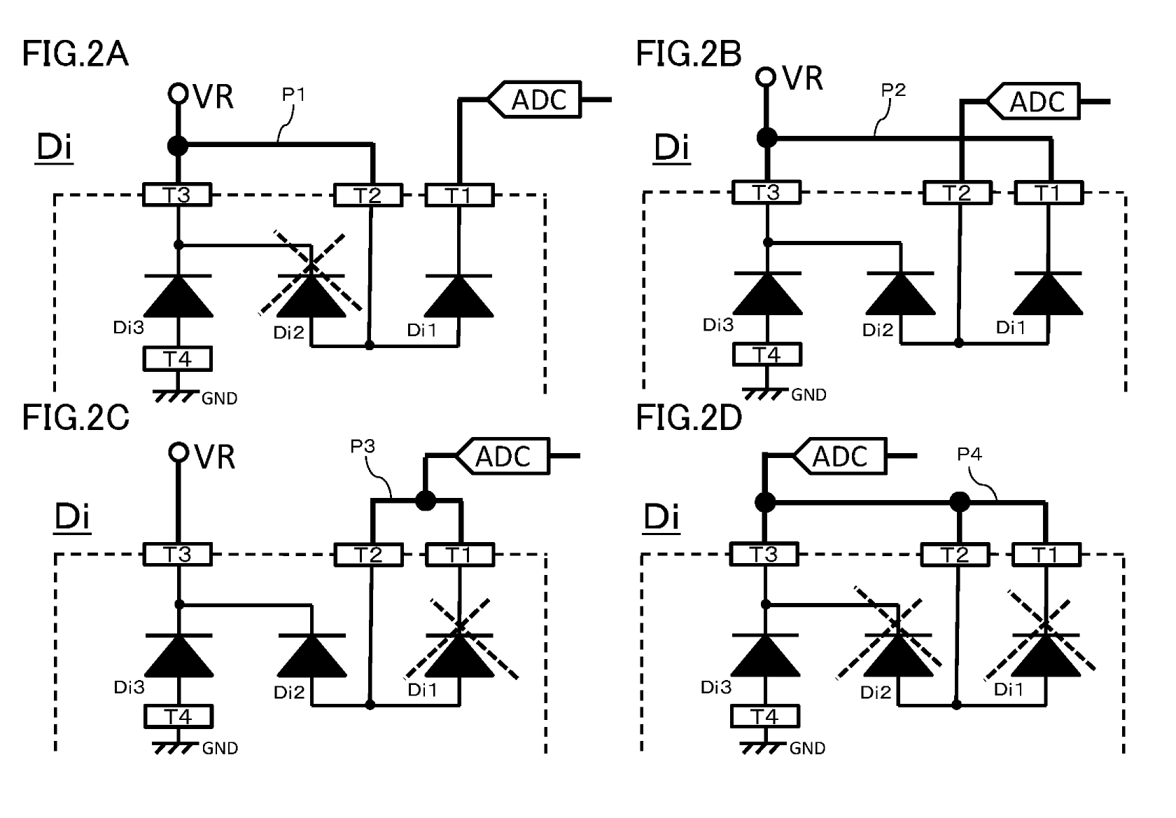

FIGS. 2A to 2D are diagrams showing examples of connections of the photodiodes of the composite photodiode Di shown in FIG. 1 for better understanding of the above description. In other words, FIGS. 2A to 2D show examples of connections of the first circuit connection node T1, the second circuit connection node T2, the third circuit connection node T3, and the fourth circuit connection node T4, when the first photodiode Di1, the second photodiode Di2, and the third photodiode Di3 are individually used.

FIG. 2A shows a usage of the first photodiode Di1. The first photodiode Di1 is connected between the first circuit connection node T1 and the second circuit connection node T2. When the first photodiode Di1 is used, in order to exclude the function of the second photodiode Di2 that is not used, the second circuit connection node T2 and the third circuit connection node T3 are commonly connected with wiring P1. In this way, the cathode and anode of the second photodiode Di2 are short-circuited so as to lose the function as the photodiode. In this case, the third photodiode Di3 has no direct relationship to the first photodiode Di1, but the reverse bias voltage VR is applied between the third circuit connection node T3 and the fourth circuit connection node T4 (ground potential GND). In this way, the third photodiode Di3 functions as a photodiode. Although the reason that the third photodiode Di3 is functioned will be clarified later, the purpose is to bring the third photodiode Di3 to act as a stopper for unnecessary incident light to the third photodiode Di3, when the composite photodiode Di is formed on the semiconductor substrate. The photocurrent generated in the first photodiode Di1 is detected by the ADC connected to the cathode, i.e. the first circuit connection node T1. The function of the third photodiode Di3 as a stopper is used not only for the first photodiode Di1 but also for the second photodiode Di2. Therefore, the predetermined reverse bias voltage VR is always applied between the third circuit connection node T3 and the fourth circuit connection node T4.

FIG. 2B shows a usage of the second photodiode Di2. The second photodiode Di2 is connected between the second circuit connection node T2 and the third circuit connection node T3. When the second photodiode Di2 is used, two connection methods are considered. One of them is shown in FIG. 2B. In the connection of FIG. 2B, the first circuit connection node T1 and the third circuit connection node T3 are commonly connected with wiring P2. Therefore, the first photodiode Di1, which has no direct relationship to the function of the second photodiode Di2, also functions as a photodiode. In this case, the ADC is connected to the second circuit connection node T2, and hence the ADC in the connection of FIG. 2B processes the sum of photocurrent of the second photodiode Di2 and photocurrent of the first photodiode Di1. Note that as described above, the third photodiode Di3 has no direct relationship to the second photodiode Di2, but the reverse bias voltage VR is applied between the third circuit connection node T3 and the fourth circuit connection node T4 (ground potential GND). In this way, the third photodiode Di3 functions as a photodiode. Although the reason that the third photodiode Di3 is functioned will be clarified later, the purpose is to use the third photodiode Di3 as a stopper for unnecessary incident light to the second photodiode Di2, when the composite photodiode Di is formed on a semiconductor substrate. The photocurrent generated in the second photodiode Di2 is processed by the ADC connected to the anode, i.e. the second circuit connection node T2.

FIG. 2C shows another connection when the second photodiode Di2 is used. Unlike FIG. 2B, in the connection of FIG. 2C, the first circuit connection node T1 and the second circuit connection node T2 are commonly connected with wiring P3. In this way, the cathode and anode of the first photodiode Di1 are short-circuited so that the function as a photodiode is lost. In this case, the ADC is connected to the second circuit connection node T2 and the first circuit connection node T1, and hence the ADC in the connection of FIG. 2C processes only photocurrent of the second photodiode Di2. Note that as described above, the third photodiode Di3 has no direct relationship to the second photodiode Di2, but the reverse bias voltage VR is applied between the third circuit connection node T3 and the fourth circuit connection node T4 (ground potential GND). In this way, the third photodiode Di3 functions as a photodiode. Although the reason that the third photodiode Di3 is functioned will be clarified later, the purpose is to use the third photodiode Di3 as a stopper for unnecessary incident light to the second photodiode Di2, when the composite photodiode Di is formed on a semiconductor substrate. The photocurrent generated in the second photodiode Di2 is processed by the ADC connected to the anode, i.e. the second circuit connection node T2.

FIG. 2D shows a usage of the third photodiode Di3. The third photodiode Di3 is connected between the third circuit connection node T3 and the fourth circuit connection node T4 (ground potential GND). When the third photodiode Di3 is used, all the first circuit connection node T1, the second circuit connection node T2, and the third circuit connection node T3 are commonly connected with wiring P4. In this way, the cathode and anode of each of the first photodiode Di1 and the second photodiode Di2 are short-circuited so that the function as a photodiode is lost. In this case, the ADC is connected to the third circuit connection node T3 (as well as the second circuit connection node T2 and the first circuit connection node T1), and hence photocurrent of only the third photodiode Di3 is processed by the ADC.

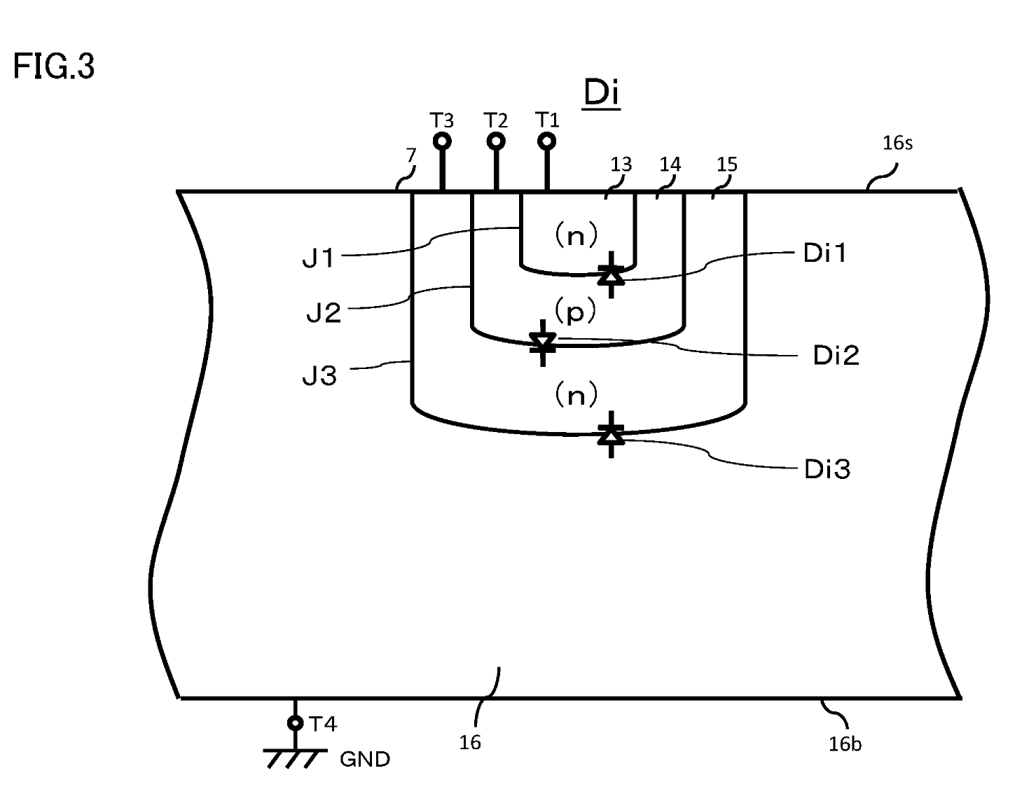

FIG. 3 schematically shows a cross-sectional view when the composite photodiode Di shown in FIGS. 1 and 2A to 2D according to the present invention is formed in the semiconductor substrate. It has an npnp structure, which is constituted of a first n-type region 13, a first p-type region 14, a second n-type region 15, and a p-type semiconductor substrate 16, which are formed in order from a front surface 16s to a back surface 16b of the p-type semiconductor substrate 16. The second n-type region 15 is formed inside the p-type semiconductor substrate 16, and the first p-type region 14 is formed in an inner region of the second n-type region 15. Further, the first n-type region 13 is formed in an inner region of the first p-type region 14. In this way, the first photodiode Di1, the second photodiode Di2, and the third photodiode Di3 are formed from the front surface 16s toward the back surface 16b of the p-type semiconductor substrate 16.

The first circuit connection node T1 is connected to the first n-type region 13. The second circuit connection node T2 is connected to the first p-type region 14. The third circuit connection node T3 is connected to the second n-type region 15. The fourth circuit connection node T4 is connected to the p-type semiconductor substrate 16. Note that the fourth circuit connection node T4, i.e. the p-type semiconductor substrate 16 is connected to the ground potential GND.

The impurity concentration of the first n-type region 13 is 1×10¹⁹/cm³ to 1×10²⁰/cm³, for example. The impurity concentration of the first p-type region 14 is 1×10¹⁶/cm³ to 1×10¹⁷/cm³, for example. The impurity concentration of the second n-type region 15 is 5×10¹⁸/cm³ to 5×10¹⁹/cm³, for example. The impurity concentration of the p-type semiconductor substrate 16 is 4×10¹⁵/cm³ to 5×10¹⁵/cm³, for example. The impurity concentrations of the individual regions are not limited to the above values but are appropriately set as one of design matters.

The first photodiode Di1 includes a first pn junction portion J1 formed between the first p-type region 14 and the first n-type region 13, and the depth thereof is e.g. 0.09 μm to 0.17 μm from the front surface 16s of the p-type semiconductor substrate 16, for example. The first pn junction portion J1 has a U-shape. When the first circuit connection node T1 is applied with a potential higher than the potential of the second circuit connection node T2, i.e. the reverse bias voltage, a depletion layer is formed. The depletion layer width thereof is increased in proportion to the reverse bias voltage. When the depletion layer width is increased, a region to which the first photodiode Di1 responds is enlarged so that the photocurrent is increased.

The second photodiode Di2 includes a second pn junction portion J2 formed between the first p-type region 14 and the second n-type region 15, and the depth thereof is larger than the pn junction portion J1 of the first photodiode Di1 and is, for example, 1.0 μm to 1.8 μm from the front surface 16s of the p-type semiconductor substrate 16. The second pn junction portion J2 has a U-shape similarly to the first pn junction portion J1. When the third circuit connection node T3 is applied with a potential higher than the potential of the second circuit connection node T2, i.e. the reverse bias voltage, a depletion layer is formed. The depletion layer width thereof is increased in proportion to the reverse bias voltage. The depletion layer width is larger than the depletion layer width (W1) formed in the first pn junction portion J1, in comparison by the same reverse bias voltage. As shown in FIG. 1, the depletion layer width generated in the third pn junction portion J3 is the largest in comparison by the same reverse bias voltage VR, so that a relationship of W3>W2>W1 is satisfied.

The third photodiode Di3 includes the third pn junction portion J3 formed between the p-type semiconductor substrate 16 and the second n-type region 15, and the depth thereof is larger than the pn junction portion of the photodiode Di2 and is, for example, 3.2 μm to 5.9 μm from the front surface 16s of the p-type semiconductor substrate 16. The third pn junction portion J3 has a U-shape similarly to the first pn junction portion J1 and the second pn junction portion J2. When the third circuit connection node T3 is applied with a potential higher than the potential of the fourth circuit connection node T4 (GND), i.e. the reverse bias voltage, a depletion layer is formed, and the depletion layer width thereof is increased in proportion to the reverse bias voltage.

An advantage in that the composite photodiode Di includes the first photodiode Di1, the second photodiode Di2, and the third photodiode Di3, which have different depths, is as described below. As the wavelength of light is longer, the penetration depth to the p-type semiconductor substrate 16 is tend to be larger. If there are a plurality of wavelength regions of light components to be detected like the composite photodiode Di, one of the first photodiode Di1, the second photodiode Di2, and the third photodiode Di3 can efficiently detect light.

For example, the first photodiode Di1 is suitable for detecting a component of blue color wavelength region (e.g. 420 nm to 480 nm) or green color wavelength region (e.g. 500 nm to 560 nm). The second photodiode Di2 is suitable for detecting a component of green color wavelength region or red color wavelength region (e.g. 590 nm to 680 nm). In addition, the third photodiode Di3 is suitable for detecting a component of infrared wavelength region (e.g. 700 nm to 1300 nm).

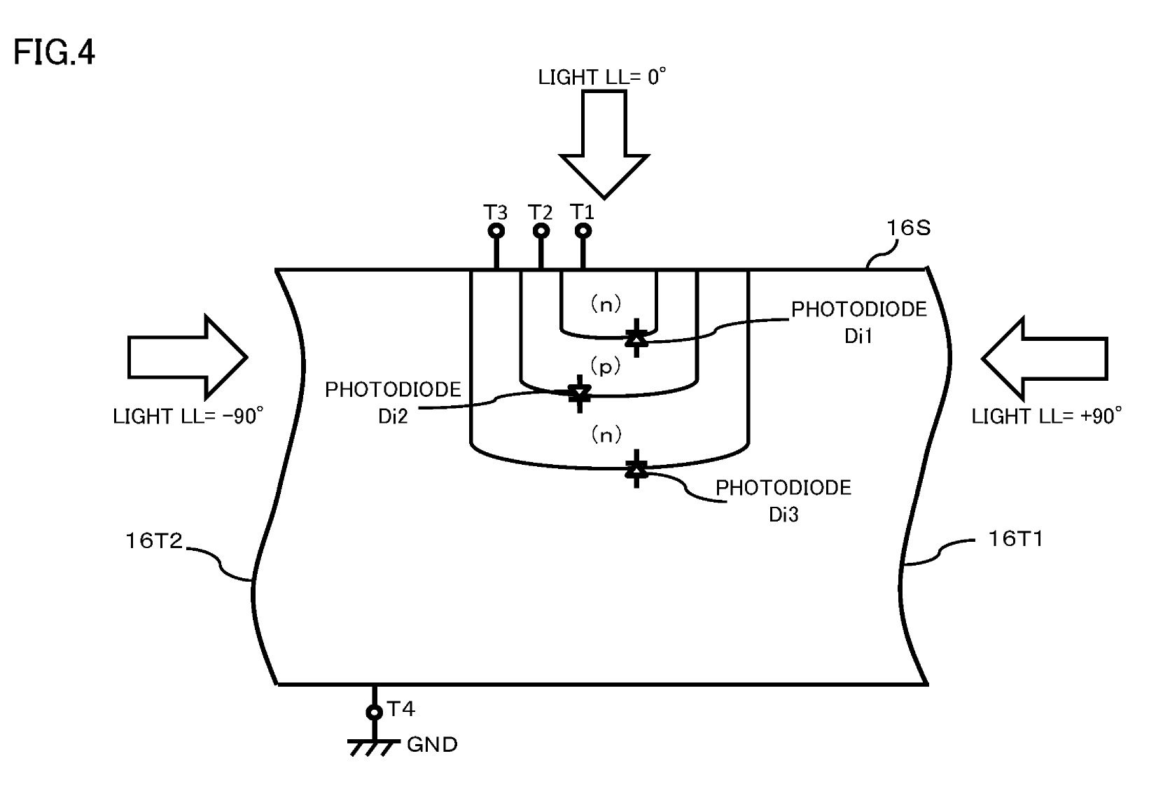

FIG. 4 shows irradiation directions (angles) of light irradiating the composite photodiode Di when the composite photodiode Di shown in FIG. 3 and output characteristics thereof are measured and evaluated. Here, the output characteristics are one evaluation item that is used for quantitatively grasping influence to photocurrent of the composite photodiode by the incident light from a side surface or end surface of the chip (semiconductor substrate).

In FIG. 4, light LL=0°, light LL=+90°, and light LL=−90° indicate irradiation directions (angles) of light irradiating the composite photodiode Di. The light LL=0° indicates that light irradiates from the direction perpendicular to the front surface 16s. The light LL=+90° indicates that light irradiates from the side surface 16T1, i.e. from the direction perpendicular to the light LL=0°. The light LL=−90° indicates that light irradiates from the opposite side surface 16T2, i.e. from the direction perpendicular to the light LL=0°. Therefore the irradiation directions of the light LL=+90° and the light LL=−90° are different by 180 degrees. Note that in the measurement this time, it was tried to irradiate with measuring light not only from the three direction of the light LL=0°, the light LL=+90°, and the light LL=−90° but also from many directions of angles. A measurement result is as follows.

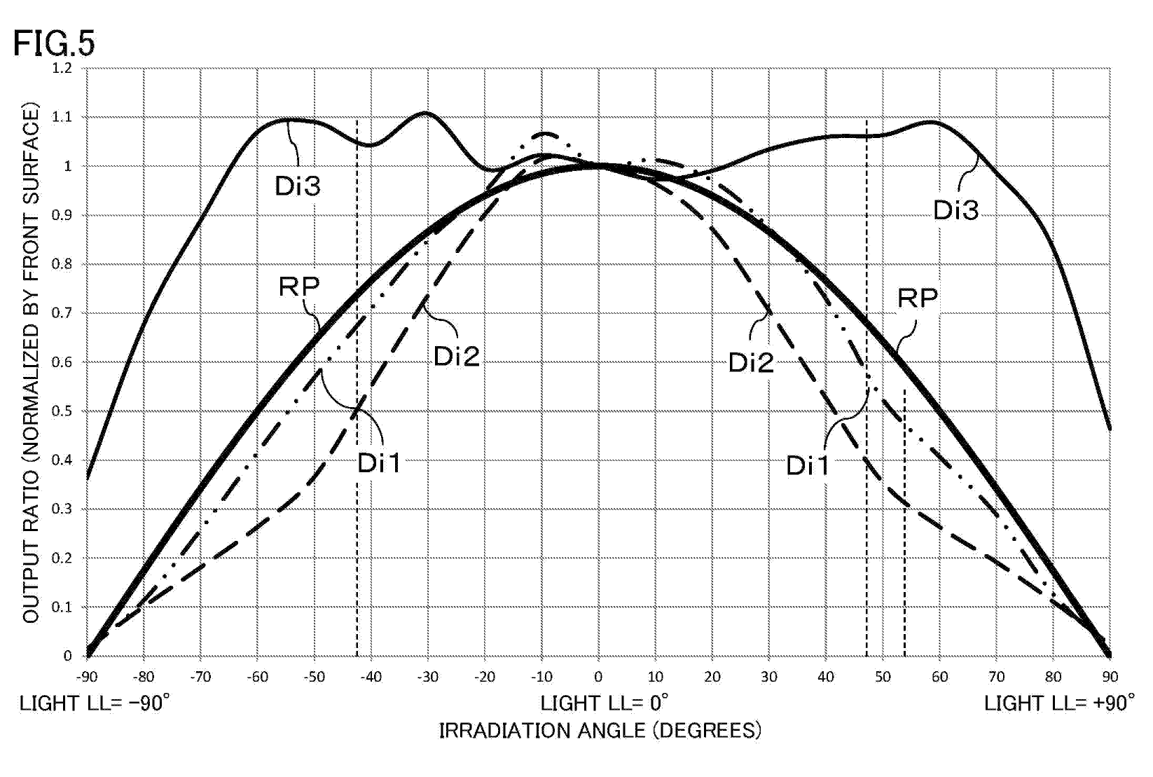

FIG. 5 shows output characteristics of the first photodiode Di1 (double-dot dashed line), the second photodiode Di2 (broken line), and the third photodiode Di3 (solid line), obtained by irradiating the composite photodiode Di shown in FIG. 4 with light from an incandescent lamp from each angle, digital-converting photocurrent output from the three photodiodes with the ADC, and normalizing the converted digital values. The horizontal axis represents the irradiation angle, and the vertical axis represents the normalized photocurrent output.

The output characteristics shown in FIG. 5 are measured by using the composite photodiode Di in the connection state shown in each of FIGS. 2A to 2D. With reference to FIG. 5, the output characteristics of the first photodiode Di1 is shown in such a manner that the output at the irradiation angle of 0 degrees (light LL=0° is 1.0. In order to show the outputs at other irradiation angles in normalized values, the photocurrent at the irradiation angle of 0 degrees (light LL=0°) is set to 1.0. It is understood that the output of the first photodiode Di1 at the irradiation angle of 45 degrees is approximately 0.62, the output at the irradiation angle of 52 degrees and its vicinity is ½ of the output at the irradiation angle of 0 degrees (light LL=0°), and the output at the irradiation angle of 90 degrees (light LL=90°) is approximately 0.02, i.e. 1/50 of the output at the irradiation angle of 0 degrees (light LL=0°). The output at the irradiation angle of 90 degrees is the output when light enters from the side surface of the chip, and as this value is smaller, influence of light entering from the side surface of the chip is smaller, which means better for a photodiode.

It is understood that the output characteristics of the first photodiode Di1 show substantially the same characteristics for the irradiation angle of the light LL=−90° and for the irradiation angle of the light LL=+90°. As clear in FIG. 3, it is appropriate to understand that because the first pn junction portion J1 of the first photodiode Di1 is completely enclosed by the second n-type region 15 and the first p-type region 14, the light entering from the side surface 16T1 or 16T2 is absorbed by these regions and is blocked to reach the first pn junction portion J1. In particular, it is estimated that an expansion of the depletion layer formed in the third pn junction portion J3 between the second n-type region 15 and the p-type semiconductor substrate 16 blocks the light entering from the side surface.

With reference to FIG. 5, the output characteristics of the second photodiode Di2 are shown in such a manner that the output at the irradiation angle of 0 degrees (light LL=0°) is 1.0. In order to show the outputs at other irradiation angles in normalized values, the photo current at the irradiation angle of 0 degrees (light) LL=0°) is set to 1.0. It is understood that the output of the second photodiode Di2 at the irradiation angle of 45 degrees is approximately 0.43, and the output at the irradiation angle of 90 degrees is approximately 0.02, i.e. 1/50 of the output at the irradiation angle of 0 degrees (light LL=0°). The output at the irradiation angle of 90 degrees is the output when light enters from the side surface of the chip, and as this value is smaller, influence of light entering from the side surface of the chip is smaller, which means better for a photodiode.

It is understood that the output characteristics of the second photodiode Di2 show substantially the same characteristics for the irradiation angle of the light LL=−90° and for the irradiation angle of the light LL=+90°. As clear in FIG. 3, it is estimated that because the second pn junction portion J2 of the second photodiode Di2 is completely enclosed by the second n-type region 15, the light entering from the side surface 16T1 or 16T2 is absorbed by this region. In particular, it is estimated that the third pn junction portion J3 formed between the second n-type region 15 and the p-type semiconductor substrate 16 blocks the light entering from the chip side surface.

Symbol RP shown in FIG. 5 (thick solid line) denotes output characteristics of the first photodiode Di1 and the second photodiode Di2, expected by the present inventor at the beginning. In other words, the present inventor expected that the outputs at the light LL=+90° and the light LL=−90° become substantially zero, and the result was substantially satisfied.

With reference to FIG. 5, the output characteristics of the third photodiode Di3 are shown in such a manner that the output at the irradiation angle of 0 degrees (light LL=0°) is 1.0 similarly to the first photodiode Di1 and the second photodiode Di2. In order to show the outputs at other irradiation angles in normalized values, the photocurrent at the irradiation angle of 0 degrees (light LL=0°) is set to 1.0. It is understood that the output of the third photodiode Di3 show substantially the same characteristics for the irradiation angle of the light LL=−90° and for the irradiation angle of the light LL=90°, but the output characteristics are largely different from those of the other two photodiodes.

The output characteristics of the third photodiode Di3 are largely different from those of the other two photodiodes because the side surfaces 16T1 and 16T2 of the chip (p-type semiconductor substrate 16) constitute a part of the third photodiode Di3, and the p-type semiconductor substrate 16 constitutes the anode of the third photodiode Di3, so that it is directly exposed to the light entering from the side surface 16T1 or 16T2. The output of the third photodiode Di3 is 1.0 or higher at the irradiation angle of 0 to ±65 degrees, and the output at the irradiation angle of ±90 degrees is approximately 0.4 times of the output at the light LL=0°) , so as to respond to a wide range of irradiation angles. In other words, as the output of the third photodiode Di3 is higher, a blocking ratio of unnecessary incident light to the first photodiode Di1 and the second photodiode Di2 becomes larger. Note that the third photodiode Di3 outputs a certain level for the incident light from the side surface 16T1 or 16T2, and hence it is estimated that there is also the effect of blocking the incident light from the back surface 16b of the p-type semiconductor substrate 16, to a certain extent.

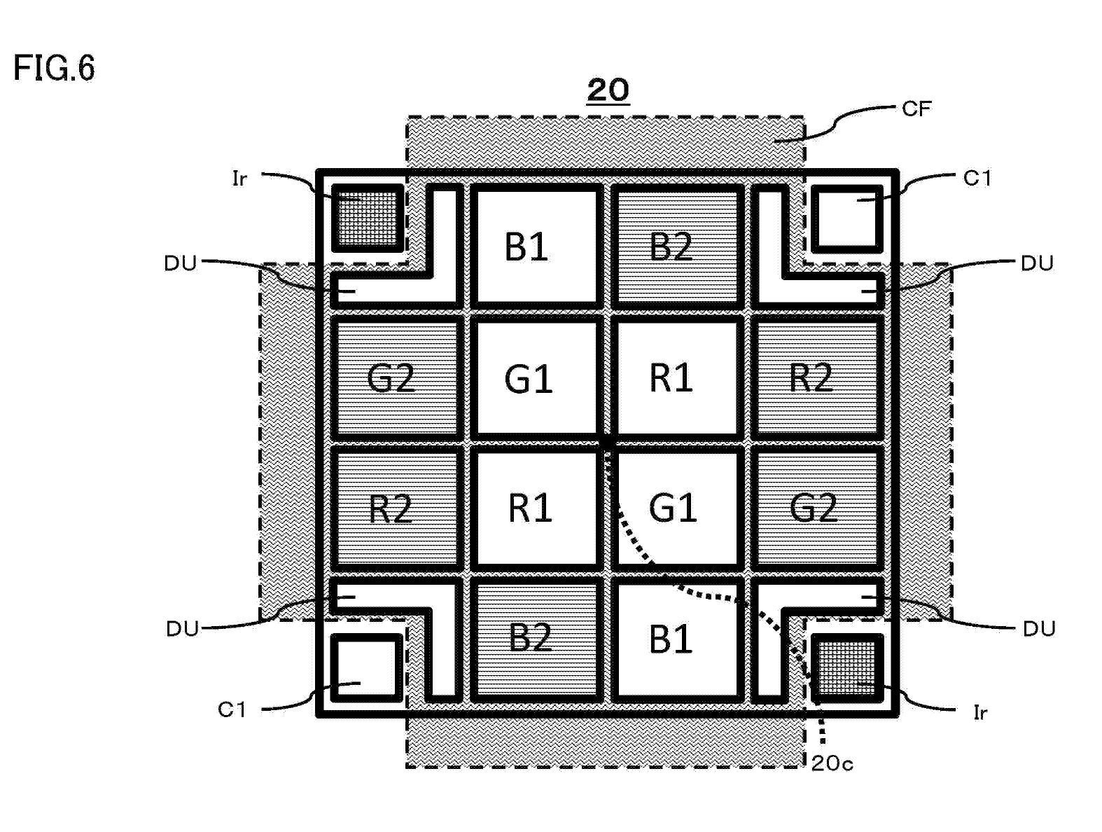

FIG. 6 shows a layout diagram of a light-receiving region 20 when the composite photodiode Di shown in FIGS. 1, 2, and 3 is used for the photosensor of the present invention. An overview of the photosensor cannot be read from FIG. 6. However, as disclosed in Patent Document 3 that is proposed by the present inventor, the photosensor includes the ADC and an ADC logic circuit besides the light-receiving region 20. The light-receiving region 20 includes infrared light receiving portions Ir, blue color light receiving portions B1 and B2, green color light receiving portions G1 and G2, red color light receiving portions R1 and R2, and ambient light receiving portions C1. The light-receiving region 20 is formed as a part of the photosensor in the semiconductor substrate, and is packed in a package having a plurality of external terminals (e.g. eight pins) as a final product.

The light-receiving region 20 has a rectangular shape in a plan view, for example, and the center thereof is denoted by symbol 20c. The green color light receiving portions G1 are disposed in the vicinity of the center 20c of the light-receiving region 20, and the green color light receiving portions G2 are disposed next to them a little apart from the center 20c.

The blue color light receiving portions B1 and B2, the green color light receiving portions G1 and G2, and the red color light receiving portions R1 and R2 are covered with an infrared light cut filter CF in order to cut unnecessary infrared light.

Similarly to the green color light receiving portions G1, the red color light receiving portions R1 are disposed in the vicinity of the center 20c of the light-receiving region 20, and the red color light receiving portions R2 are disposed next to them a little apart from the center 20c.

The blue color light receiving portions B1 and B2 are disposed at positions a little apart from the center 20c of the light-receiving region 20, unlike the green color light receiving portion G1 and the red color light receiving portion R1.

The light receiving portions G1, G2, R1, R2, B1, and B2 constitute an RGB light receiving portion. The RGB light receiving portion is a part of the light-receiving region 20.

The green color light receiving portions G1 and G2 are constituted of the first photodiode Di 1, the second photodiode Di2, or a combination of them shown in FIGS. 1, 2, and 3.

The red color light receiving portions RI and R2 are constituted of the second photodiode Di2 shown in FIGS. 1, 2, and 3.

The blue color light receiving portions B1 and B2 are constituted of the first photodiode Di1 shown in FIGS. 1, 2, and 3.

The light receiving portion C1 constitutes the ambient light receiving portion. The light receiving portions C1 are disposed at two corners of the light-receiving region 20, which are most apart from the center 20c of the light-receiving region 20. The light receiving portion C1 receives light of all wavelength regions reaching the light-receiving region 20. Therefore, the light receiving portions C1 are not covered with the infrared light cut filter CF that is used for the light receiving portions G1, G2, R1, R2, B1, and B2.

The light receiving portion Ir constitutes the infrared light receiving portion. The light receiving portions Ir are disposed at two corners that are most apart from the center 20c of the light-receiving region 20 and are not occupied with the light receiving portion C1. The light receiving portion Jr detects infrared light reaching the light-receiving region 20. As a matter of course, the light receiving portions Ir are not covered with the infrared light cut filter CF.

The light receiving portion Ir is constituted of the third photodiode Di3 shown in FIGS. 1, 2, and 3.

For example, L-shaped dummy regions DU are disposed at the boundary of the light receiving portion C1 of the ambient light and the RGB light receiving portion (G1, G2, R1, R2, B1, B2) and at the boundary of the light receiving portion Ir and the RGB light receiving portion. The dummy region DU is a photosensitive region, and a bipolar transistor or the like is disposed in this photosensitive region, for example. By disposing the dummy regions DU, a predetermined margin is secured in arrangement of the infrared light cut filter CF, and the light entering the RGB light receiving portion is substantially completely separated from the light entering the other light receiving portions.

Undesired incident light from side surface and end surface of the chip becomes problem mostly in case of infrared light having large penetrating power. It is because visible light or the like is mostly absorbed to disappear by a chip edge and its periphery. As to the third photodiode Di3, the depletion layer in the third pn junction portion J3 is disposed at an endmost of the chip viewed from the chip side surface. Further, the third photodiode Di3 is suitable for detecting a component in the infrared wavelength region. These characteristics are important for manufacturing a photosensor having small angle dependence.

<Summary>

Hereinafter, various structures of the invention disclosed in this specification are summarized using the numerals and symbols in the above description. Such description will be useful for understanding the spirit of the present invention. However, the use of numerals and symbols do not limit the technical scope recited in the claims.

The composite photodiode (Di) according to the present invention includes the first photodiode (Di1), the second photodiode (Di2), and the third photodiode (Di3), each of which has an anode and a cathode. The cathode of the first photodiode (Di1) is connected to the first circuit connection node (T1). The anode of the first photodiode is commonly connected to the anode of the second photodiode (Di2) and is connected to the second circuit connection node (T2). The cathode of the second photodiode (Di2) is commonly connected to the cathode of the third photodiode (Di3) and is connected to the third circuit connection node (T3). The anode of the third photodiode (Di3) is connected to the fourth circuit connection node (T4). The fourth circuit connection node (T4) is connected to the reference potential (e.g. the ground potential (GND)).

In the composite photodiode (Di) according to the present invention, when the same reverse bias voltage (VR) is applied between anode and cathode of each of the first photodiode (Di1), the second photodiode (Di2), and the third photodiode (Di3), the depletion layer widths W1, W2, and W3 of them are set to be larger in order of the third photodiode (Di3), the second photodiode (Di2), and the first photodiode (Di1) (W3>W2>W1).

In the composite photodiode (Di) according to the present invention, when the first photodiode (Di1) is used, the first circuit connection node (T1) is applied with a potential higher than or equal to the potential of the second circuit connection node (T2).

In the composite photodiode (Di) according to the present invention, when the first circuit connection node (T1) is applied with a potential higher than or equal to the potential of the second circuit connection node (T2), the third circuit connection node (T3) is commonly connected to the second circuit connection node (T2), and the fourth circuit connection node is connected to the ground potential (GND).

In the composite photodiode (Di) according to the present invention, when the second photodiode (Di2) is used, the third circuit connection node (T3) is applied with a potential higher than or equal to the potential of the second circuit connection node (T2).

In the composite photodiode (Di) according to the present invention, when the second photodiode (Di2) is used, the first circuit connection node and the third circuit connection node are commonly connected.

In the composite photodiode (Di) according to the present invention, when the second photodiode (Di2) is used, as another circuit connection, the first circuit connection node (T1) and the second circuit connection node (T2) are commonly connected.

In the composite photodiode (Di) according to the present invention, when the first photodiode (Di1) or the second photodiode (Di2) is used, the third circuit connection node (T3) is always applied with a potential higher than or equal to the potential of the fourth circuit connection node (T4).

In the composite photodiode (Di) according to the present invention, when the third photodiode (Di3) is used, the third circuit connection node (T3) is applied with a potential higher than or equal to the potential of the fourth circuit connection node (T4).

In the composite photodiode (Di) according to the present invention, when the third circuit connection node (T3) is applied with a potential higher than or equal to the potential of the fourth circuit connection node (T4), the first circuit connection node (T1) is commonly connected to the second circuit connection node (T2), and this common connection node (T1 and T2) is commonly connected to the third circuit connection node (T3). The fourth circuit connection node (T4) is connected to the ground potential (GND)

In the composite photodiode according to the present invention, the first photodiode (Di1), the second photodiode (Di2), and the third photodiode (Di3) are constituted by using the first pn junction portion (J1), the second pn junction portion (J2), and the third pn junction portion (J3), which are formed in order from the front surface (16s) to the back surface (16b) of the p-type semiconductor substrate (16). The first pn junction portion (J1) is used for the first photodiode (Di1). The second pn junction portion (J2) is used for the second photodiode (Di2). The third pn junction portion (J3) is used for the third photodiode (Di3).

In a photosensor according to another embodiment of the present invention, one of the above-mentioned composite photodiodes (Di) is used for the light-receiving region (20).

In a photosensor according to another embodiment of the present invention, the first photodiode (Di1) is used for the green color (G) light receiving portion or the blue color (B) light receiving portion in the light-receiving region (20) of the photosensor.

In a photosensor according to another embodiment of the present invention, the second photodiode (Di2) is used for the green color (G) light receiving portion or the red color (R) light receiving portion in the light-receiving region (20) of the photosensor.

The photosensor according to another embodiment of the present invention further include the infrared light receiving portion (Ir), and the third photodiode (Di3) is used for the infrared light receiving portion (Ir).

In a photosensor according to another embodiment of the present invention, the light-receiving region (20) is constituted as an aggregation of the RGB light receiving portion and other light receiving portion on the p-type semiconductor substrate (16). The green color light receiving portions (G1, G2), the red color light receiving portions (R1, R2), and the blue color light receiving portions (B1, B2), which constitute the RGB light receiving portion, and the ambient light receiving portions and the infrared light receiving portions, which constitute the other light receiving portion, are arranged in a symmetric manner with respect to the center (20c) of the light-receiving region (20) in a plan view.

In a photosensor according to another embodiment of the present invention, the green color light receiving portions (G1, G2) and the red color light receiving portions (R1, R2) are arranged in a symmetric manner with respect to the center (20c) of the light-receiving region (20) and closest to the center (20c).

In a photosensor according to another embodiment of the present invention, the light-receiving region (20) has a rectangular shape in a plan view, and the ambient light receiving portions (C1) and the infrared light receiving portions (Ir) are respectively arranged in a symmetric manner with respect to the center (20c) of the light-receiving region (20) at four corners of the rectangular shape.

In a photosensor according to another embodiment of the present invention, the dummy regions (DU) are disposed between the ambient light receiving portion (C1) and the RGB light receiving portion, and between the infrared light receiving portion (Ir) and the RGB light receiving portion.

According to the present invention, it is possible to provide a composite photodiode and a photosensor using the same, in which incident light from a chip side surface can be blocked except for a third photodiode.

<Industrial Applicability>

The present invention can provide a composite photodiode and a photosensor using the same, which is not affected by undesired incident light from a chip side surface, with a simple connection structure without increasing manufacturing steps, and hence has high industrial applicability.

What is claimed is:

1. A composite photodiode comprising:
a first photodiode, a second photodiode, and a third photodiode, each of which has an anode and a cathode, wherein
the cathode of the first photodiode is connected to a first circuit connection node,
the anode of the first photodiode is commonly connected to the anode of the second photodiode and is connected to a second circuit connection node,
the cathode of the second photodiode is commonly connected to the cathode of the third photodiode and is connected to a third circuit connection node, and
the anode of the third photodiode is connected to a fourth circuit connection node.

2. The composite photodiode according to claim 1, wherein depletion layer widths of the first photodiode, the second photodiode, and the third photodiode when the same reverse bias voltage is applied between anode and cathode of each of the photodiodes, which are denoted by W1, W2, and W3, respectively, are set to be larger in order of the third photodiode, the second photodiode, and the first photodiode, so that W3>W2>W1 is satisfied.

3. The composite photodiode according to claim 2, wherein when the first photodiode is used, the first circuit connection node is applied with a potential higher than or equal to a potential of the second circuit connection node.

4. The composite photodiode according to claim 3, wherein when the first circuit connection node is applied with a potential higher than or equal to a potential of the second circuit connection node, the third circuit connection node is commonly connected to the second circuit connection node.

5. The composite photodiode according to claim 2, wherein when the second photodiode is used, the third circuit connection node is applied with a potential higher than or equal to a potential of the second circuit connection node.

6. The composite photodiode according to claim 5, wherein when the second photodiode is used, the first circuit connection node and the third circuit connection node are commonly connected.

7. The composite photodiode according to claim 5, wherein when the second photodiode is used, the first circuit connection node and the second circuit connection node are commonly connected.

8. The composite photodiode according to claim 1, wherein when the first photodiode or the second photodiode is used, the third circuit connection node is always applied with a potential higher than or equal to a potential of the fourth circuit connection node.

9. The composite photodiode according to claim 2, wherein when the third photodiode is used, the third circuit connection node is applied with a potential higher than or equal to a potential of the fourth circuit connection node.

10. The composite photodiode according to claim 9, wherein when the third circuit connection node is applied with a potential higher than or equal to a potential of the fourth circuit connection node, the first circuit connection node is commonly connected to the second circuit connection node, and this common connection node is connected to the third circuit connection node.

11. The composite photodiode according to claim 1, wherein
the first photodiode, the second photodiode, and the third photodiode are constituted by using a first pn junction, a second pn junction, and a third pn junction, which are formed in order from a front surface to a back surface of the p-type semiconductor substrate,
the first pn junction portion is used for the first photodiode,
the second pn junction portion is used for the second photodiode, and
the third pn junction portion is used for the third photodiode.

12. A photosensor comprising an RGB light receiving portion, wherein the composite photodiode according to claim 1 is used for the RGB light receiving portion.

13. The photosensor according to claim 12, wherein the first photodiode is used for a green color light receiving portion or a blue color light receiving portion in the RGB light receiving portion.

14. The photosensor according to claim 12, wherein the second photodiode is used for a green color light receiving portion or a red color light receiving portion in the RGB light receiving portion.

15. The photosensor according to claim 12, further comprising an infrared light receiving portion, wherein the third photodiode is used for the infrared light receiving portion.

16. The photosensor according to claim 12, wherein
a light-receiving region is constituted as an aggregation of the RGB light receiving portion and other light receiving portion on the p-type semiconductor substrate, and
the green color light receiving portion, the red color light receiving portion, and the blue color light receiving portion, which constitute the RGB light receiving portion, and the ambient light receiving portions and the infrared light receiving portions, which constitute the other light receiving portion, are arranged in a symmetric manner with respect to the center of the light-receiving region in a plan view.

17. The photosensor according to claim 16, wherein the green color light receiving portion and the red color light receiving portion are arranged in a symmetric manner with respect to the center of the light-receiving region and closest to the center.

18. The photosensor according to claim 16, wherein the light-receiving region has a rectangular shape in a plan view, and the ambient light receiving portions and the infrared light receiving portions are respectively arranged in a symmetric manner with respect to the center of the light-receiving region at four corners of the rectangular shape.

19. The photosensor according to claim 16, wherein dummy regions are disposed between the ambient light receiving portion and the RGB light receiving portion, and between the infrared light receiving portion and the RGB light receiving portion.
